(19) United States
(12) Patent Application Publication
(10) Pub. No.: US 2016/0079262 A1
(43) Pub. Date: Mar. 17, 2016

(54) SEMICONDUCTOR MEMORY DEVICE AND METHOD FOR MANUFACTURING SAME

(71) Applicant: KABUSHIKI KAISHA TOSHIBA, Tokyo (JP)

(72) Inventors: Shinji Mori, Yokkaichi (JP); Yoshio Ozawa, Kanazawa (JP); Tetsuya Kai, Tokyo (JP)

(73) Assignee: KABUSHIKI KAISHA TOSHIBA

(21) Appl. No.: 14/631,879

(22) Filed: Feb. 26, 2015

Related U.S. Application Data
(60) Provisional application No. 62/048,837, filed on Sep. 11, 2014.

(51) Int. Cl. H01L 27/115; H01L 29/04

(52) U.S. Cl. CPC H01L 27/11582; H01L 29/04

(57) ABSTRACT

According to one embodiment, a semiconductor memory device includes a conductive layer; a stacked body provided on the conductive layer and including a plurality of electrode layers separately stacked each other; a semiconductor body provided in the stacked body and extending in a stacking direction in the stacking body and including a lower end portion provided in the conductive layer; and a charge storage film provided between the semiconductor body and the plurality of electrode layers. As viewed in the stacking direction, a maximum width of the lower end portion is larger than a maximum width of the semiconductor body provided inside a bottom surface of the charge storage film.

This application is based upon and claims the benefit of priority from U.S. Provisional Patent Application 62/048,837 field on Sep. 11, 2014; the entire contents of which are incorporated herein by reference.

### FIELD

Embodiments described herein relate generally to a semiconductor memory device and a method for manufacturing same.

### BACKGROUND

A three-dimensionally structured memory device is proposed. In the memory device, a memory hole is formed in a stacked body in which an electrode layer that functions as a control gate in a memory cell is plurally stacked with an insulating film interposed between the electrode layers, and a silicon body that serves as a channel is disposed on a side wall of the memory hole with a charge storage film interposed between the side wall and the silicon body.

Currents in the cell are required to be increased in the three-dimensionally structured memory device.

### BRIEF DESCRIPTION OF THE DRAWINGS

FIG. 1 is a schematic perspective view of a memory cell array of an embodiment;

FIG. 2 is a schematic cross-sectional view of a part of memory strings of the embodiment;

FIG. 3 is an enlarged schematic sectional view of a part of the columnar section of the embodiment;

FIG. 4 to FIG. 7B are schematic cross-sectional views showing a method for manufacturing the semiconductor memory device of the embodiment;

FIG. 8 is a schematic cross-sectional view of a part of memory strings of the embodiment; and

FIG. 9 is a graph representing a characteristic of the mobility of the channel body.

### DETAILED DESCRIPTION

According to one embodiment, a semiconductor memory device includes a conductive layer; a stacked body provided on the conductive layer and including a plurality of electrode layers separately stacked each other; a semiconductor body provided in the stacked body and extending in a stacking direction in the stacking body and including a lower end portion provided in the conductive layer; and a charge storage film provided between the semiconductor body and the plurality of electrode layers. As viewed in the stacking direction, a maximum width of the lower end portion is larger than a maximum width of the semiconductor body provided inside a bottom surface of the charge storage film.

Hereinafter, an embodiment will be described with reference to the accompanying drawings. The same constituent in each drawing is given the same reference sign.

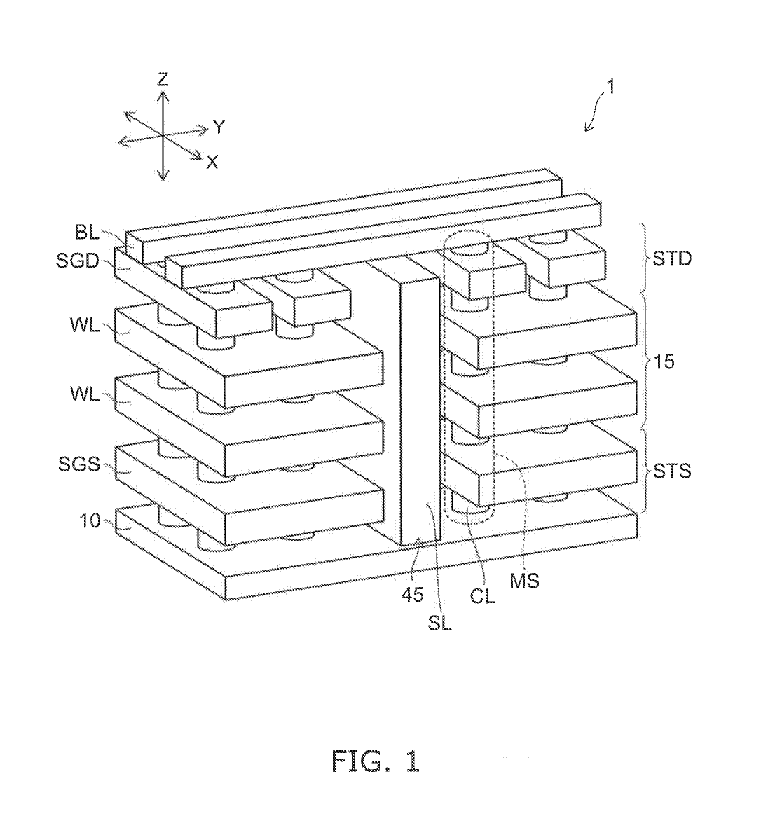

FIG. 1 is a schematic perspective view of a memory cell array 1 of the embodiment. Illustrations of an insulating layer and the like are omitted for easy understanding in FIG. 1.

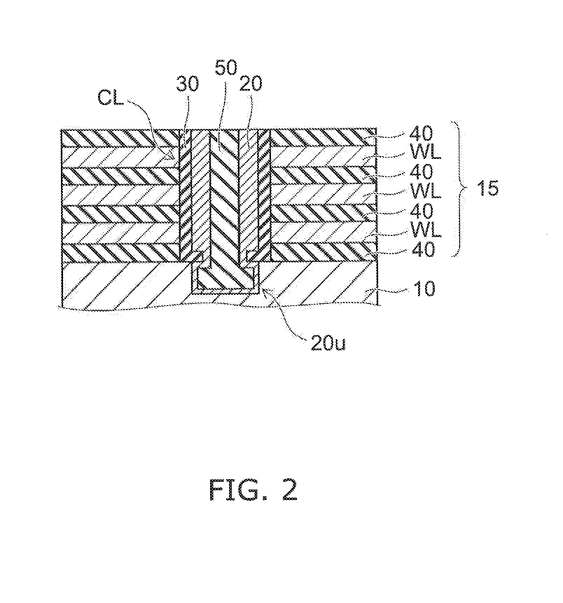

FIG. 2 is a schematic cross-sectional view of a semiconductor memory device of the embodiment. Structures that are higher than a stacked body 15 will be omitted in FIG. 2.

In FIG. 1, two directions that are parallel to the major surface of a conductive layer 10 and are orthogonal to each other are set as an X-direction and a Y-direction, and a direction that is orthogonal to both of the X-direction and the Y-direction is set as a 2-direction (direction of stacking).

The memory cell array 1 includes a plurality of memory strings MS as illustrated in FIG. 1.

A source-side selector gate SGS is disposed on the conductive layer 10 (for example, a substrate) that has conductivity through an insulating film. An insulating layer is disposed on the source-side selector gate SGS, and the stacked body 15 in which a plurality of electrode layers WL and a plurality of interlayer insulating layers 40 are alternately stacked on each other one by one is disposed on the insulating layer. The number of electrode layers WL is illustrated as an example in the drawings and is arbitrary.

The plurality of electrode layers WL is separately stacked each other. The interlayer insulating layer 40 includes an air gap.

An insulating layer is disposed on the uppermost electrode layer WL, and a drain-side selector gate SGD is disposed on the insulating layer.

The source-side selector gate SGS, the drain-side selector gate SGD, and the electrode layer WL are silicon layers that contain silicon as a main component. Boron, for example, is doped as an impurity in the silicon layer for providing conductivity. In addition, the source-side selector gate SGS, the drain-side selector gate SGD, and the electrode layer WL may include a metal silicide or may include metal. The source-side selector gate SGS, the drain-side selector gate SGD, and the electrode layer WL may be made of metal. An insulating film, for example, that mainly contains silicon oxide is disposed in the interlayer insulating layer 40.

The thickness of the drain-side selector gate SGD and the source-side selector gate SGS, for example, is greater than the thickness of one electrode layer WL. The drain-side selector gate SGD and the source-side selector gate SGS may be disposed plurally. The thickness of the drain-side selector gate SGD and the source-side selector gate SGS may be smaller than or equal to the thickness of one electrode layer WL. In this case, the drain-side selector gate SGD and the source-side selector gate SGS may be disposed plurally in the same manner as described above. The “thickness” here indicates the thickness of the stacked body 15 in the direction of stacking (Z-direction).

A columnar portion CL is disposed in the stacked body 15 extending in the Z-direction. The columnar portion CL penetrates the drain-side selector gate SGD, the stacked body 15, and the source-side selector gate SGS. The columnar portion CL, for example, is formed as a cylinder or an elliptic cylinder. The columnar portion CL is electrically connected to the conductive layer 10.

A groove 45 is disposed in the stacked body 15 penetrating the drain-side selector gate SGD, the stacked body 15, and the source-side selector gate SGS. A source layer SL is disposed in the groove 45, and the side surface of the source layer SL is covered by an insulating film. Conductive material is used as the source layer SL.

The lower end of the source layer SL is electrically connected to a channel body 20 (semiconductor body) of the columnar portion CL through the conductive layer 10. The upper end of the source layer SL is electrically connected to an unillustrated peripheral circuit (control circuit).

The source layer SL, for example, may be disposed between the conductive layer 10 and the stacked body 15. In this case, a contact portion is disposed in the groove 45, and the source layer SL is electrically connected to the control circuit through the contact portion.

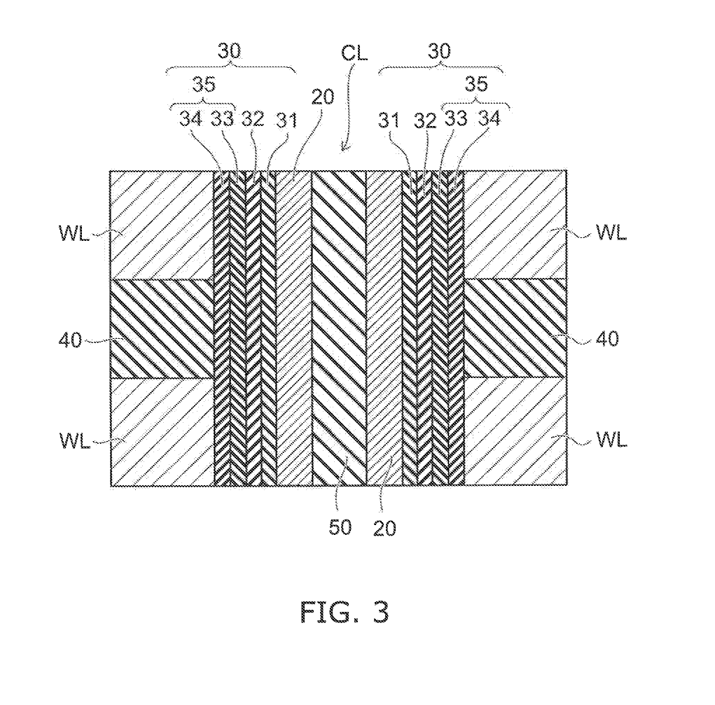

FIG. 3 is a schematic cross-sectional view of an enlarged part of the columnar portion CL of the embodiment.

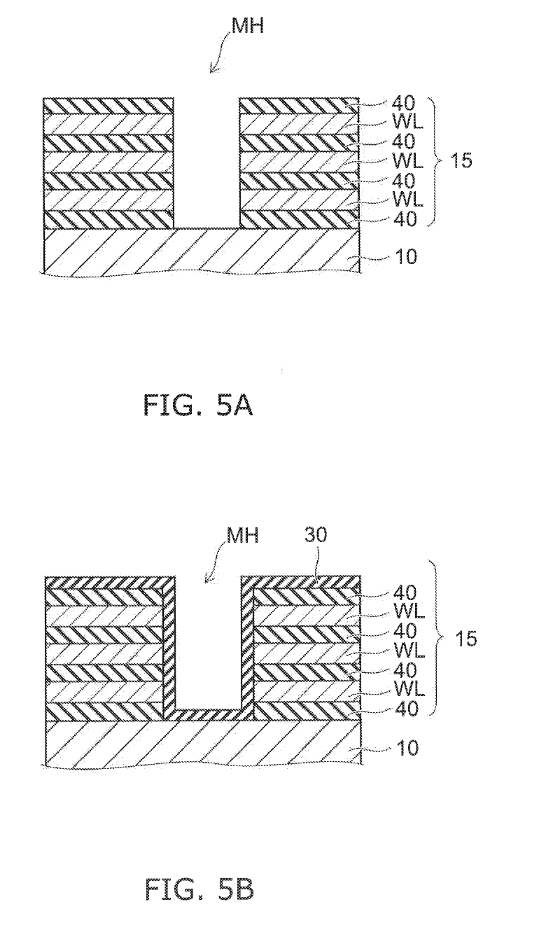

The columnar portion CL is formed in a memory hole MH (in FIG. 5A) that is formed in the stacked body 15 which includes the plurality of electrode layers WL and the plurality of interlayer insulating layers 40. The channel body 20 is disposed in the memory hole MH as a semiconductor channel.

Polysilicon, for example, is used as the channel body 20. Polysilicon, for example, is formed through a process of heating amorphous silicon to be crystallized.

The channel body 20 is disposed as a tube that extends in the direction of stacking in the stacked body 15. The upper end of the channel body 20 is connected to a bit line BL (wiring) illustrated in FIG. 1, and the lower end of the channel body 20 is connected to the conductive layer 10 through a lower end portion 20u. Each bit line BL extends in the Y-direction.

A memory film 30 is disposed between the electrode layer WL and the channel body 20. The memory film 30 includes a block insulating film 35, a charge storage film 32, and a tunnel insulating film 31.

The block insulating film 35, the charge storage film 32, and the tunnel insulating film 31 are disposed between the electrode layer WL and the channel body 20 in this order from the electrode layer WL side. The block insulating film 35 is in contact with the electrode layer WL, and the tunnel insulating film 31 is in contact with the channel body 20. The charge storage film 32 is disposed between the block insulating film 35 and the tunnel insulating film 31.

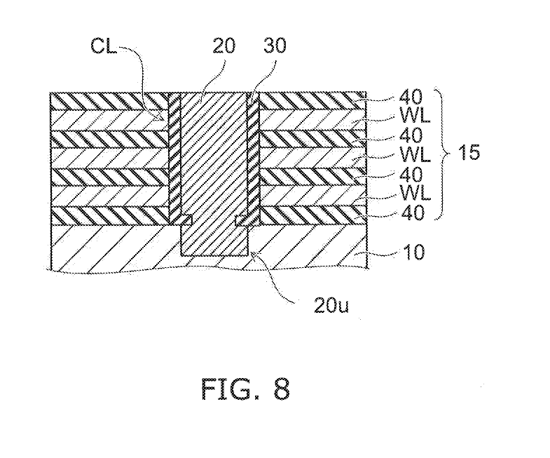

The electrode layer WL surrounds the channel body 20 with the memory film 30 interposed therebetween. A core insulating film 50 is disposed inside the channel body 20. The inside of the memory film 30, for example, may be filled with a columnar channel body 20 that does not include the core insulating film 50 as illustrated in FIG. 8.

The channel body 20 functions as a channel in a memory cell, and the electrode layer WL functions as a control gate of the memory cell. The charge storage film 32 functions as a data memory layer that stores charges implanted from the channel body 20. That is, the memory cell structured in a manner in which the control gate surrounds the channel is formed at the intersection part of the channel body 20 and each electrode layer WL.

A semiconductor memory device of the embodiment can freely delete or write data electrically and can hold the contents of the memory even when power is turned off.

The memory cell, for example, is a charge trap type. The charge storage film 32, for example, is a silicon nitride film and plurally includes trap sites that capture charges.

The tunnel insulating film 31 serves as a potential barrier when charges are implanted to the charge storage film 32 from the channel body 20 or when charges stored in the charge storage film 32 are diffused into the channel body 20. The tunnel insulating film 31, for example, is a silicon oxide film.

Alternatively, a stacked film (ONO film) that is structured in a manner in which a silicon nitride film is interposed between a pair of silicon oxide films may be used as the tunnel insulating film 31. When the ONO film is used as the tunnel insulating film 31, a deletion operation is performed with a low electric field compared with a case of using a single silicon oxide film.

The block insulating film 35 prevents charges stored in the charge storage film 32 from being diffused into the electrode layer WL. The block insulating film 35 includes a cap film 34 that is disposed in contact with the electrode layer WL and a block film 33 that is disposed between the cap film 34 and the charge storage film 32.

The block film 33, for example, is a silicon oxide film. The cap film 34 has a higher dielectric constant than silicon oxide and, for example, is a silicon nitride film. Disposing such cap film 34 in contact with the electrode layer WL can suppress back tunneling of electrons that are implanted from the electrode layer WL during deletion. That is, using a stacked film of a silicon oxide film and a silicon nitride film as the block insulating film 35 can increase the ability to block charges.

A drain-side selector transistor STD is disposed in the upper end portion of the columnar portion CL, and a source-side selector transistor STS is disposed in the lower end portion of the columnar portion CL in the memory string MS as illustrated in FIG. 1.

The memory cell, the drain-side selector transistor STD, and the source-side selector transistor STS are vertical transistors in which currents flow in the direction of stacking (Z-direction) in the stacked body 15.

The drain-side selector gate SGD functions as the gate electrode (control gate) of the drain-side selector transistor STD. An insulating film is disposed between the drain-side selector gate SGD and the channel body 20 functioning as a gate insulating film of the drain-side selector transistor STD.

The source-side selector gate SGS functions as the gate electrode (control gate) of the source-side selector transistor STS. An insulating film is disposed between the source-side selector gate SGS and the channel body 20 functioning as a gate insulating film of the source-side selector transistor STS.

A plurality of memory cells is disposed between the drain-side selector transistor STD and the source-side selector transistor STS with each electrode layer WL as the control gate.

The plurality of memory cells, the drain-side selector transistor STD, and the source-side selector transistor STS are connected in series through the channel body 20 and constitute one memory string MS. The plurality of memory cells is disposed three-dimensionally in the X-direction, the Y-direction, and the Z-direction by arranging the memory strings MS plurally in the X-direction and the Y-direction.

The lower end portion 20u (the bottom surface and the side surface) of the channel body 20 protrudes toward the conductive layer 10 as illustrated in FIG. 2. The lower end portion 20u is not covered by the memory film 30. The channel body 20 that is higher than the lower end portion 20u is covered by the memory film 30. The memory film 30, for example, does not protrude toward the conductive layer 10.

The surrounds of the lower end portion 20u are covered by the conductive layer 10. Accordingly, the channel body 20 is electrically connected to the conductive layer 10 through the lower end portion 20u. The channel body 20 is electrically connected to the source layer SL through the lower end portion 20u and the conductive layer 10.

According to the embodiment, the lower end portion 20u of the channel body 20 protrudes toward the conductive layer 10. For this reason, the conductive layer 10 is in contact with the side surface and the bottom surface of the lower end portion 20u. That is, the area of contact between the channel body 20 and the conductive layer 10 is great. According to such a structure of the embodiment, the contact resistance between the channel body 20 and the conductive layer 10 can be lowered compared with a structure in which the channel body does not protrude toward the conductive layer, and only the bottom surface of the channel body is in contact with the conductive layer.

Furthermore, the diameter of the lower end portion 20u of the channel body 20 is greater than the diameter of the channel body 20 that is disposed higher than the lower end portion 20u according to the embodiment. The bottom surface of the memory film 30 is in contact with the lower end portion 20u of the channel body 20 and, for example, is covered by the lower end portion 20u.

The circumference of the side surface of the lower end portion 20u is greater than the circumference of the channel body 20 that is disposed higher than the lower end portion 20u. The area of the bottom surface of the lower end portion 20u is greater than the area of the X-Y planar cross section of the channel body 20 that is disposed higher than the lower end portion 20u.

As viewed in the stacking direction, a maximum width of the lower end portion 20u is larger than a maximum width of the semiconductor body 20 provided inside a bottom surface of the memory film 30.

According to the embodiment, a second hole is formed in the conductive layer 10 through reactive ion etching (RIE), and thereafter, the diameter of the second hole is enlarged through another etching process as will be described below. Therefore, the diameter of the lower end portion 20u is greater than the diameter of the channel body 20 that is disposed higher than the lower end portion 20u. Accordingly, the area of contact between the channel body 20 and the conductive layer 10 can be increased, and the contact resistance between the channel body 20 and the conductive layer 10 can be lowered.

In addition to the above description, for example, the bottom surface of the memory film 30 is in contact with the lower end portion 20u of the semiconductor body 20. Thus, an electric field caused by the lower end portion 20u is not concentrated at the memory cell provided in the bottom of the stacked body 15. Due to this, variations in the threshold voltage of the memory cell can be suppressed.

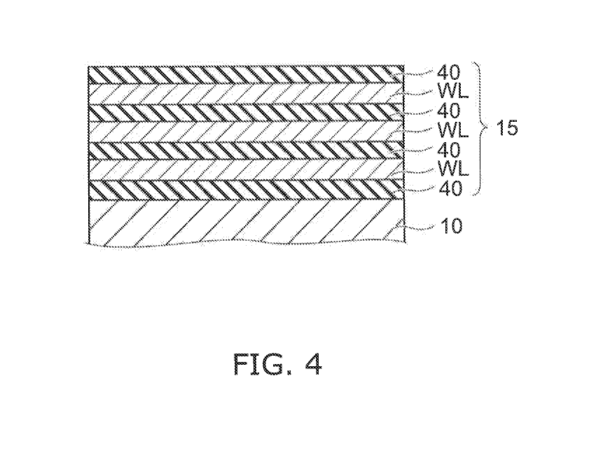

Next, a method for manufacturing the semiconductor memory device of the embodiment will be described with reference to FIG. 4 to FIG. 7B.

The stacked body 15 in which the plurality of interlayer insulating layers 40 and the plurality of electrode layers WL are alternately stacked on each other is formed on the conductive layer 10 as illustrated in FIG. 4. The source-side selector gate SGS, for example, or the source layer SL may be formed between the conductive layer 10 and the stacked body 15.

A stacked body 15, for example, in which the plurality of interlayer insulating layers 40 and a plurality of sacrificing layers of which the material is different from that of the interlayer insulating layer 40 are alternately stacked on each other may be formed, and the electrode layer WL may be formed after the sacrificing layer is selectively removed through another process.

The memory hole MH is formed through RIE penetrating the stacked body 15 as illustrated in FIG. 5A. The conductive layer 10 is exposed in the bottom portion of the memory hole MH.

The memory film 30 illustrated in FIG. 3 is conformally formed on the inner wall (the side wall and the bottom portion) of the memory hole MH and on the upper surface of the stacked body 15 as illustrated in FIG. 5B.

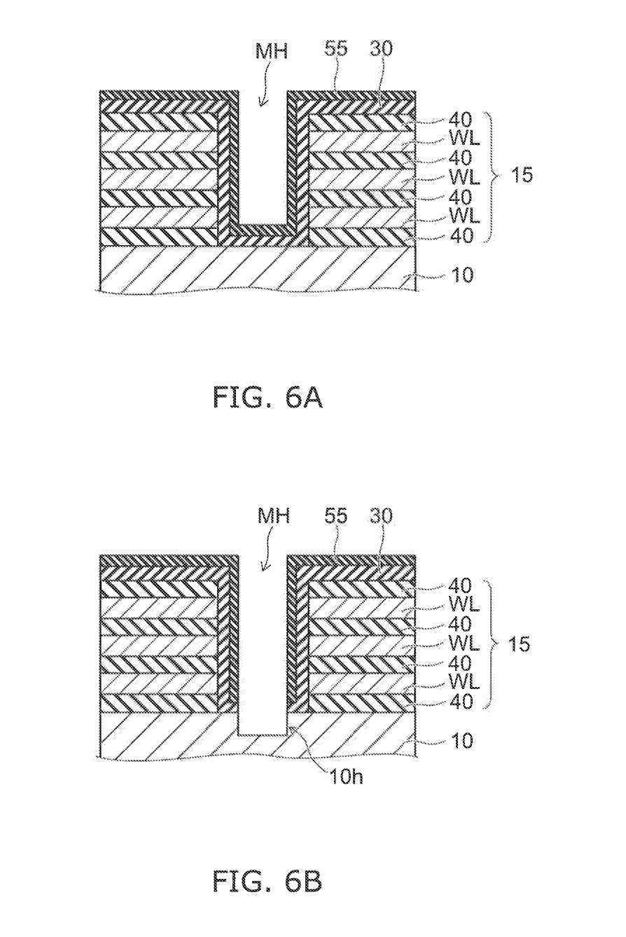

A cover film 55 is conformally formed inside the memory film 30 as illustrated in FIG. 6A. Amorphous silicon, for example, is used as the cover film 55.

Alternatively, silicon-germanium (SiGe) is used as the cover film 55. When the cover film 55 that includes SiGe is removed through a process that is described below, the process can be performed at a low temperature. This can prevent the memory film 30 and the like from deterioration.

A hole 10h is formed penetrating from the bottom surface of the cover film 55 until the memory film 30 to reach the conductive layer 10 as illustrated in FIG. 6B. The hole 10h, for example, is formed through RIE with an unillustrated mask. Accordingly, the conductive layer 10 is exposed on the inner wall (the side surface and the bottom surface) of the hole 10h.

Thereafter, a chemical oxide film that is formed inside the cover film 55 and on the surface of the conductive layer 10 which is exposed to the hole 10h is removed through, for example, a dilute hydrofluoric acid (DHF) process.

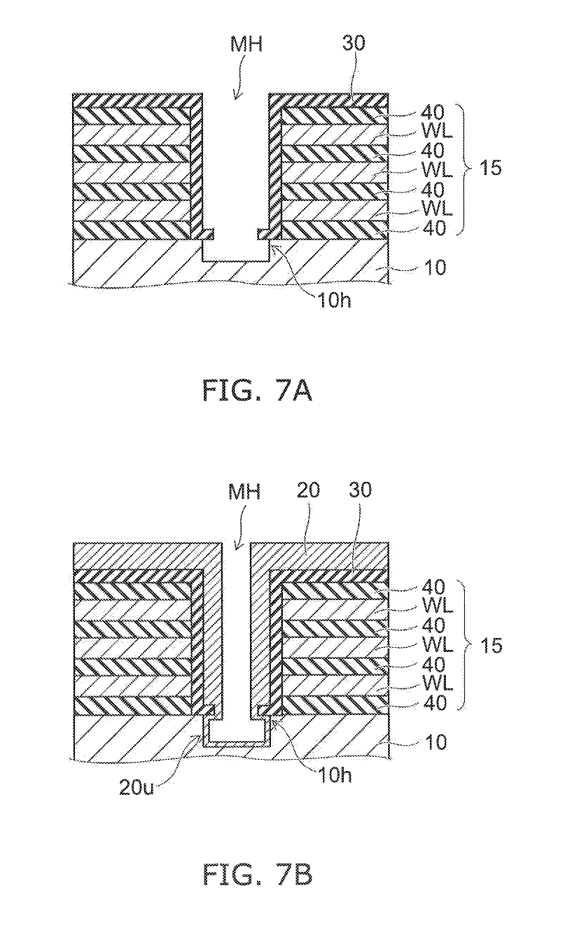

The cover film 55 that is formed inside the memory film 30 is completely removed through an etching process through the memory hole MH as illustrated in FIG. 7A.

At the same time, the conductive layer 10 that is exposed to the inner wall of the hole 10h is recessed.

A wet etching process, for example, that uses alkali-based chemicals or chemical dry etching (CDE) is used as the etching process. An annealing process in a halogen-based gas atmosphere (a gas atmosphere including at least one of HCl, Cl₂, and F₂) is used as CDE. According to the above method, the cover film 55 can be completely removed without deterioration of the memory film 30. The diameter of the hole 10h that is enlarged by the recessing of the conductive layer 10 is greater than the diameter of the memory hole MH.

The channel body 20 is formed inside the memory film 30 and on the inner wall of the hole 10h as illustrated in FIG. 7B. The channel body 20 is conformally formed inside the memory film 30 and on the inner wall of the hole 10h. Alternatively, the memory hole MH and the hole 10h, for example, may be filled with the channel body 20 as illustrated in FIG. 8. Amorphous silicon, for example, is used as the channel body 20.

The core insulating film 50 is formed inside the channel body 20 after the process in FIG. 7B. The memory hole MH and the hole 10h are filled with the core insulating film 50.

Next, the memory film 30, the channel body 20, and the core insulating film 50 that are formed on the stacked body 15 are removed, and the columnar portion CL is formed as illustrated in FIG. 2.

Thereafter, a heating process, for example, is performed on the columnar portion CL. Accordingly, amorphous silicon that is used in the channel body 20 is crystallized, and polysilicon is formed. The temperature of the heating process, for example, is greater than or equal to 550° C.

Wiring and the like that are electrically connected to the channel body 20 are formed on the stacked body 15, and the semiconductor memory device is formed according to the embodiment.

According to the embodiment, the memory film 30 is formed, and thereafter, the cover film 55 is formed inside the memory film 30. Accordingly, deterioration of the memory film 30 can be suppressed when RIE is used to form the hole 10h.

Furthermore, the cover film 55 that is formed inside the memory film 30 is removed after the hole 10h is formed. Thereafter, the channel body 20 is formed inside the memory film 30.

When, for example, the cover film 55 that is formed inside the memory film 30 is not removed, and the channel body 20 is formed inside the cover film 55, a natural oxide film is formed between the cover film 55 and the channel body 20. Accordingly, polysilicon that is formed through the heating process is separated into the cover film 55 and the channel body 20 with the oxide film interposed therebetween. That is, polysilicon is thinly formed. In this case, crystal grain boundaries that are formed per a unit area are increased. Accordingly, resistance caused by grain boundary scattering is increased, and currents in the memory cell may be decreased.

Regarding this, according to the embodiment, the cover film 55 and a natural oxide film are not formed when forming polysilicon through the heating process. Thick polysilicon that does not include a natural oxide film thereinside can be formed. In this case, crystal grain boundaries that are formed per a unit area are decreased, and a decrease in currents in the memory cell can be suppressed.

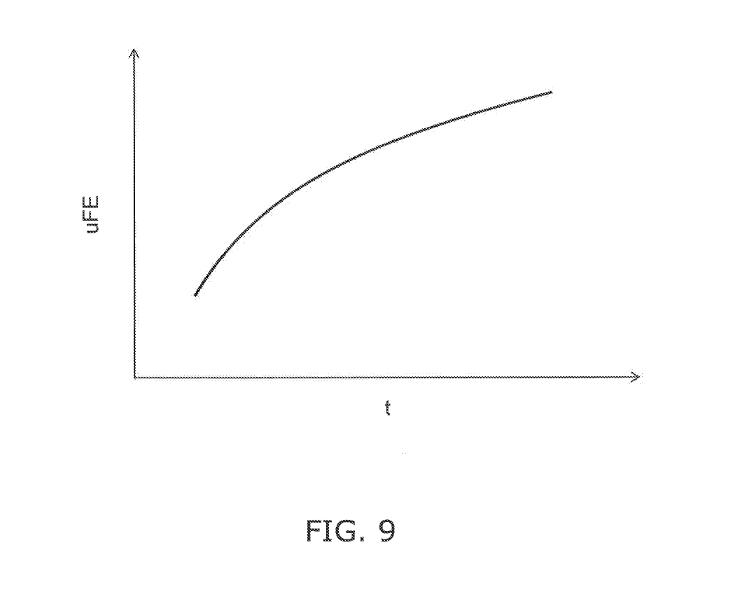

FIG. 9 is a graph representing a characteristic of the mobility of the channel body. The horizontal axis of the graph represents the thickness of the channel body 20 (polysilicon). The thickness is greater toward the right side. The vertical axis of the graph represents the mobility of the channel body 20. The mobility is higher toward the upper side.

It can be read that the mobility tends to be increased along with the thickness of the channel body 20 being increased as illustrated in FIG. 9. According to the embodiment, the channel body 20 can be thickly formed having great crystal grains compared with the above-described state where the cover film 55 and a natural oxide film are formed. Accordingly, the mobility of the channel body 20 can be increased. This can increase currents in the cell and the speed of operation of the memory.

In addition to the above description, the conductive layer 10 that is exposed to the hole 10h is recessed at the same time as removal of the cover film 55 according to the embodiment. For this reason, the diameter of the lower end portion 20u of the channel body 20 is greater than the diameter of the channel body 20 that is formed higher than the lower end portion 20u. That is, as viewed in the stacking direction, a maximum width of the lower end portion 20u is larger than a maximum width of the semiconductor body 20 provided inside a bottom surface of the memory film 30. Accordingly, the contact resistance between the channel body 20 and the conductive layer 10 can be lowered.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a conductive layer;
a stacked body provided on the conductive layer and including a plurality of electrode layers separately stacked each other;
a semiconductor body provided in the stacked body and extending in a stacking direction in the stacking body and including a lower end portion provided in the conductive layer; and
a charge storage film provided between the semiconductor body and the plurality of electrode layers,
as viewed in the stacking direction, a maximum width of the lower end portion being larger than a maximum width of the semiconductor body provided inside a bottom surface of the charge storage film.

2. The device according to claim 1, wherein
the lower end portion of the semiconductor body is covered by the conductive layer.

3. The device according to claim 1, further comprising:
an insulating film provided inside the semiconductor body.

4. The device according to claim 1, wherein
the semiconductor body is provided as a column and does not include an insulating film inside the semiconductor body.

5. The device according to claim 1, wherein
the bottom surface of the charge storage film is provided in the stacked body.

6. The device according to claim 1, wherein
the bottom surface of the charge storage film is in contact with the lower end portion of the semiconductor body.

7. The device according to claim 1, wherein
the semiconductor body includes polysilicon.

8. A method for manufacturing a semiconductor memory device comprising:
forming a stacked body on a conductive layer, the stacked body including a plurality of electrode layers separately stacked each other;
forming a first hole penetrating the stacked body and extending in a direction of stacking in the stacked body;
forming a film including a charge storage film on a side wall of the first hole;
forming a cover film inside the film including the charge storage film;
forming a second hole penetrating a bottom surface of the cover film and a bottom surface of the film including the charge storage film to reach the conductive layer;
removing the cover film by etching through the first hole and exposing the film including the charge storage film; and
forming a semiconductor body inside the film including the charge storage film and on a side wall of the second hole.

9. The method according to claim 8, wherein
the conductive layer exposed to the second hole is recessed, and the diameter of the second hole is enlarged at the time of the etching that removes the cover film.

10. The method according to claim 8, wherein
the first hole and the second hole are formed through reactive ion etching (RIE).

11. The method according to claim 8, wherein
the cover film is removed through a wet process.

12. The method according to claim 11, wherein
a process liquid of the wet process includes an alkali-based chemical.

13. The method according to claim 8, wherein
the cover film is removed through chemical dry etching (CDE).

14. The method according to claim 13, wherein
an etching gas of the CDE includes at least one of HCl, Cl₂, and F₂.

15. The method according to claim 8, wherein
the cover film includes silicon-germanium.

16. The method according to claim 8, further comprising:
forming an insulating film inside the semiconductor body.

17. The method according to claim 8, wherein
the first hole and the second hole are filled with the semiconductor body as columnar.

18. The method according to claim 8, wherein
the semiconductor body is crystallized through a heating process after being formed as an amorphous silicon film.

19. The method according to claim 18, wherein
the temperature of the heating process is greater than or equal to 550° C.
